(19) United States
(12) Patent Application Publication
(10) Pub. No.: US 2008/0118229 A1
(43) Pub. Date: May 22, 2008

(54) ITERATIVE CODE SYSTEM FOR STREAMING HDDs

(75) Inventor: William Gene Bliss, Thornton, CO (US)

Correspondence Address: GARLICK HARRISON & MARKISON, P.O. BOX 160727, AUSTIN, TX, 78716-0727, US

(73) Assignee: BROADCOM CORPORATION, Irvine, CA (US)

(21) Appl. No.: 11/860,158

(22) Filed: Sep. 24, 2007

Related U.S. Application Data
(60) Provisional application No. 60/860,121, filed on Nov. 20, 2006.

(51) Int. Cl. H04N 7/015; G11C 29/42

(52) U.S. Cl. 386/123; 714/769; 714/E11.062

(57) ABSTRACT

Iterative code system for streaming hard disk drives (HDDs). A novel approach is presented by which any of a wide variety of error correcting codes can be applied within devices that include or interface to HDDs or other memory storage devices that provide streaming information. A means is provided by which at least two separate clock domains are employed such that the streaming information can be provided at a first rate according to a first clock domain, and the decoding processing of the streaming information can be provided at a second rate according to a second clock domain. Using this approach, a wide variety of error correcting codes can employed, including those whose decoding processing would not be possible if required to operate at the typically high rates at which streaming information is oftentimes provided from HDDs or other memory storage devices.

### CROSS REFERENCE TO RELATED PATENTS/PATENT APPLICATIONS

### Provisional Priority Claims

The present U.S. Utility patent application claims priority pursuant to 35 U.S.C. § 119(e) to the following U.S. Provisional patent application which is hereby incorporated herein by reference in its entirety and made part of the present U.S. Utility patent application for all purposes:

1. U.S. Provisional Application Ser. No. 60/860,121, entitled “Iterative code system for streaming HDDs,” (Attorney Docket No. BP5585), filed 11-20-2006, pending.

### INCORPORATION BY REFERENCE

The following U.S. Utility patent application is hereby incorporated herein by reference in its entirety and is made part of the present U.S. Utility patent application for all purposes:

1. U.S. Utility patent application Ser. No. 02-27-2007, entitled “Iterative code system for streaming HDDs,” (Attorney Docket No. BP5585), filed 11/711,506, pending.

### BACKGROUND OF THE INVENTION

1. Technical Field of the Invention

The invention relates generally to memory storage devices; and, more particularly, it relates to memory storage devices that operate using streaming information.

2. Description of Related Art

As is known, many varieties of memory storage devices (e.g. disk drives), such as magnetic disk drives are used to provide data storage for a host device, either directly, or through a network such as a storage area network (SAN) or network attached storage (NAS). Typical host devices include stand alone computer systems such as a desktop or laptop computer, enterprise storage devices such as servers, storage arrays such as a redundant array of independent disks (RAID) arrays, storage routers, storage switches and storage directors, and other consumer devices such as video game systems and digital video recorders. These devices provide high storage capacity in a cost effective manner.

Certain devices that employ hard disk drives (HDDs) are sometimes implemented within applications that employ or require streaming information. Some examples of such applications include those that perform playback of some form of digital data (e.g., digital audio or digital video information). One example of a digital audio player is a portable digital audio device that includes some type of HDD that is operable to perform playback of digital audio information that can comport with any of a wide variety of formats or standards. Even another example of such a device that is operable to perform playback of digital data (e.g., digital audio or digital video information) is a device that is designed to perform playback of digital video (e.g., a DVR (Digital Video Recorder) type device). Many modern STBs (Set Top Boxes) that are designed to provide decoded information to a display device (e.g., some type of television) also include some form or memory storage as well. Some devices are stand-alone and operate also to record and/or playback such digital information to a display device.

The speed at which the digital information is provided from the HDD or other storage means within these devices typically is provided at a very fast rate. Oftentimes, the speed at which the digital information is provided from the HDD or other storage means is such that certain error correction decoding approaches are presently incapable to receive, decode, and output the information at those rates. There exists a need in the art for a means by which certain and a wider variety of error correction can be applied to devices that include or interface to memory storage devices that provide digital information in a streaming format.

### BRIEF SUMMARY OF THE INVENTION

The present invention is directed to apparatus and methods of operation that are further described in the following Brief Description of the Several Views of the Drawings, the Detailed Description of the Invention, and the claims. Other features and advantages of the present invention will become apparent from the following detailed description of the invention made with reference to the accompanying drawings.

### BRIEF DESCRIPTION OF THE SEVERAL VIEWS OF THE DRAWINGS

FIG. 1 illustrates an embodiment of a disk drive unit.

FIG. 2 illustrates an embodiment of an apparatus that includes a disk controller.

FIG. 3A illustrates an embodiment of a handheld audio unit.

FIG. 3B illustrates an embodiment of a handheld video unit.

FIG. 3C illustrates an embodiment of a wireless communication device.

FIG. 3D illustrates an embodiment of a television.

FIG. 3E illustrates an embodiment of a HD (High Definition) television.

FIG. 3F illustrates an embodiment of an audio device.

FIG. 4 and FIG. 5 illustrate embodiments of systems that are operable to perform decoding of streaming information.

FIG. 6 illustrates an alternative embodiment of a physical interleaving of data on a disk within a HDD or other memory storage system.

FIG. 7 and FIG. 8 illustrate other embodiments of systems that are operable to perform decoding of streaming information.

FIG. 9, FIG. 10, and FIG. 11 illustrates embodiments of systems that are operable to perform decoding of streaming information by employing some type of parallel architecture.

FIG. 12 and FIG. 13 illustrate embodiments of methods that are operable to perform decoding of streaming information.

### DETAILED DESCRIPTION OF THE INVENTION

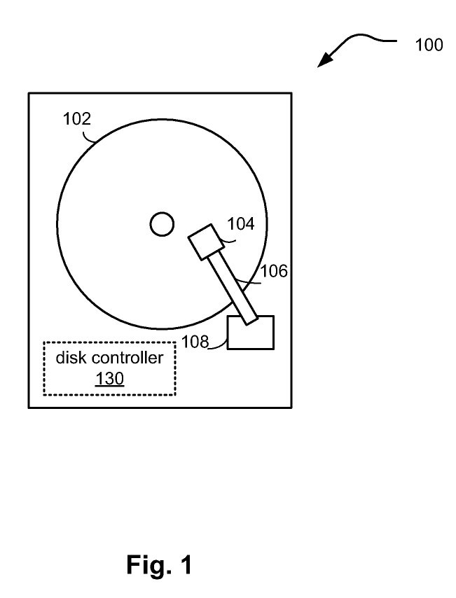

FIG. 1 illustrates an embodiment of a disk drive unit 100. In particular, disk drive unit 100 includes a disk 102 that is rotated by a servo motor (not specifically shown) at a velocity such as 3600 revolutions per minute (RPM), 4200 RPM, 4800 RPM, 5,400 RPM, 7,200 RPM, 10,000 RPM, 15,000 RPM; however, other velocities including greater or lesser velocities may likewise be used, depending on the particular application and implementation in a host device. In one possible embodiment, disk 102 can be a magnetic disk that stores information as magnetic field changes on some type of magnetic medium. The medium can be a rigid or non-rigid, removable or non-removable, that consists of or is coated with magnetic material.

Disk drive unit 100 further includes one or more read/write heads 104 that are coupled to arm 106 that is moved by actuator 108 over the surface of the disk 102 either by translation, rotation or both. A disk controller 130 is included for controlling the read and write operations to and from the drive, for controlling the speed of the servo motor and the motion of actuator 108, and for providing an interface to and from the host device.

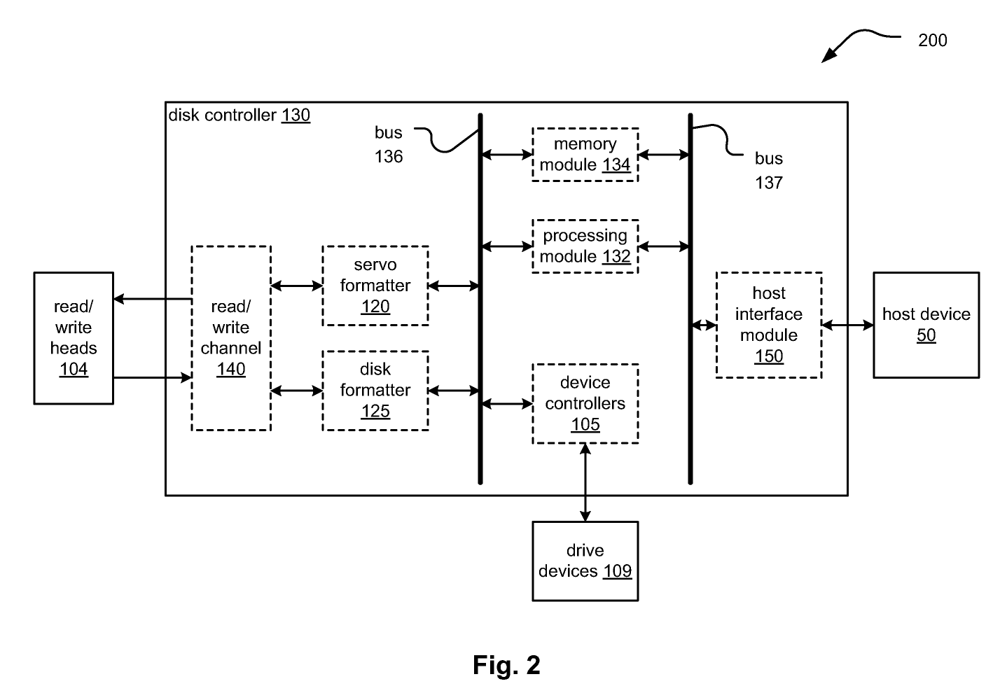

FIG. 2 illustrates an embodiment of an apparatus 200 that includes a disk controller 130. In particular, disk controller 130 includes a read/write channel 140 for reading and writing data to and from disk 102 through read/write heads 104. Disk formatter 125 is included for controlling the formatting of data and provides clock signals and other timing signals that control the flow of the data written to, and data read from disk 102. Servo formatter 120 provides clock signals and other timing signals based on servo control data read from disk 102. Device controllers 105 control the operation of drive devices 109 such as actuator 108 and the servo motor, etc. Host interface 150 receives read and write commands from host device 50 and transmits data read from disk 102 along with other control information in accordance with a host interface protocol. In one embodiment, the host interface protocol can include, SCSI, SATA, enhanced integrated drive electronics (EIDE), or any number of other host interface protocols, either open or proprietary that can be used for this purpose.

Disk controller 130 further includes a processing module 132 and memory module 134. Processing module 132 can be implemented using one or more microprocessors, micro-controllers, digital signal processors, microcomputers, central processing units, field programmable gate arrays, programmable logic devices, state machines, logic circuits, analog circuits, digital circuits, and/or any devices that manipulates signal (analog and/or digital) based on operational instructions that are stored in memory module 134. When processing module 132 is implemented with two or more devices, each device can perform the same steps, processes or functions in order to provide fault tolerance or redundancy. Alternatively, the function, steps and processes performed by processing module 132 can be split between different devices to provide greater computational speed and/or efficiency.

Memory module 134 may be a single memory device or a plurality of memory devices. Such a memory device may be a read-only memory, random access memory, volatile memory, non-volatile memory, static random access memory (SRAM), dynamic random access memory (DRAM), flash memory, cache memory, and/or any device that stores digital information. Note that when the processing module 132 implements one or more of its functions via a state machine, analog circuitry, digital circuitry, and/or logic circuitry, the memory module 134 storing the corresponding operational instructions may be embedded within, or external to, the circuitry comprising the state machine, analog circuitry, digital circuitry, and/or logic circuitry. Further note that, the memory module 134 stores, and the processing module 132 executes, operational instructions that can correspond to one or more of the steps or a process, method and/or function illustrated herein.

Disk controller 130 includes a plurality of modules, in particular, device controllers 105, processing module 132, memory module 134, read/write channel 140, disk formatter 125, and servo formatter 120 that are interconnected via bus 136 and bus 137. The host interface 150 can be connected to only the bus 137 and communicates with the host device 50. Each of these modules can be implemented in hardware, firmware, software or a combination thereof, in accordance with the broad scope of the present invention. While a particular bus architecture is shown in FIG. 2 with buses 136 and 137, alternative bus architectures that include either a single bus configuration or additional data buses, further connectivity, such as direct connectivity between the various modules, are likewise possible to implement the features and functions included in various embodiments.

In one possible embodiment, one or more modules of disk controller 130 are implemented as part of a system on a chip (SoC) integrated circuit. In an embodiment, this SoC integrated circuit includes a digital portion that can include additional modules such as protocol converters, linear block code encoding and decoding modules, etc., and an analog portion that includes device controllers 105 and optionally additional modules, such as a power supply, etc. In a further embodiment, the various functions and features of disk controller 130 are implemented in a plurality of integrated circuit devices that communicate and combine to perform the functionality of disk controller 130.

When the drive unit 100 is manufactured, disk formatter 125 writes a plurality of servo wedges along with a corresponding plurality of servo address marks at equal radial distance along the disk 102. The servo address marks are used by the timing generator for triggering the “start time” for various events employed when accessing the media of the disk 102 through read/write heads 104.

A variety of applications of HDD or other memory storage devices can include and benefit from various aspects of the invention. Generally speaking, those applications that operate using streaming information can benefit significantly. By employing the ability to operate the decoding processing within a different clock domain that the clock domain in which streaming information is provided from the HDD or other memory storage device allows the ability to use a wide variety of error correction codes that would not be feasible or practical if the decoding processing is required to operate at the same rate at which the streaming information is provided from the HDD or other memory storage device.

Also, within such applications that operate using streaming information, the rate at which the information typically needs to be provided to an output device (e.g., a user device such as an apparatus that is operable to playback digital audio data or digital video data) is generally much less than the rate at which information is provided from the HDD or other memory storage device. The information provided from the disk (e.g., the HDD or other memory storage device) may be referred to as ‘bursty’ since the information generally needs to be provided at a much faster rate than needed when it comes to provide the streaming information to an output device (e.g., a user device that is operable to playback digital audio data or digital video data).

The rate at which the bursty information is provided from the HDD or other memory storage device is oftentimes referred to as the disk rate, and this disk rate is generally much larger than the rate at which information needs to be provided to an output device. Nevertheless, a typical prior art approach is to provide some form of HDD or other memory storage device within these applications that still provides streaming information at a very high rate (i.e., a very high disk rate). Because of this, the remaining components within the processing path (i.e., the decoding aspects particularly) is also constrained to operate at that same high rate. In other words, within the prior art, the typical approach is to require all subsequent modules and/or functional blocks that operate to process streaming information provided from a HDD or other memory storage device at the very same rate at which the streaming information is provided from the HDD or other memory storage device.

This requirement is oftentimes very difficult to meet, and it also prohibits the use of anything in the processing path that cannot meet the very high speed processing requirements dictated by the requirement to operate at the very high disk rate.

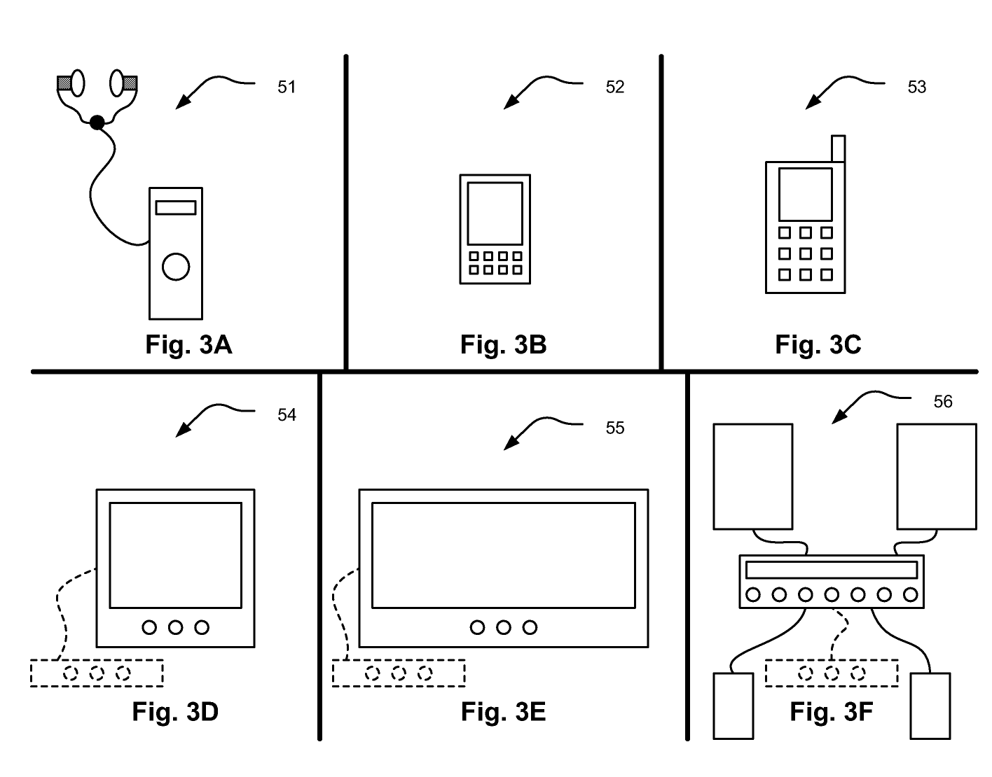

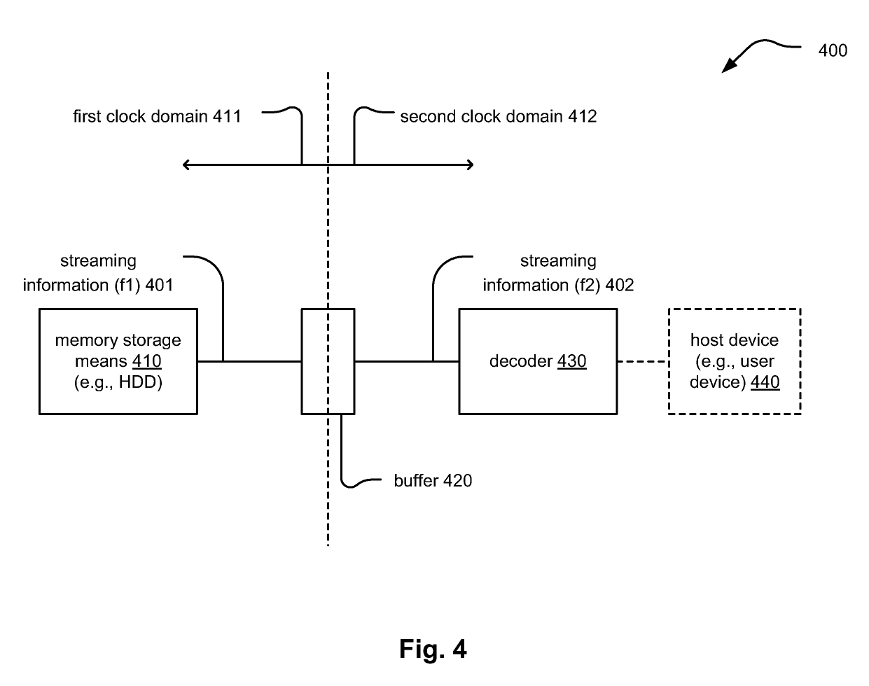

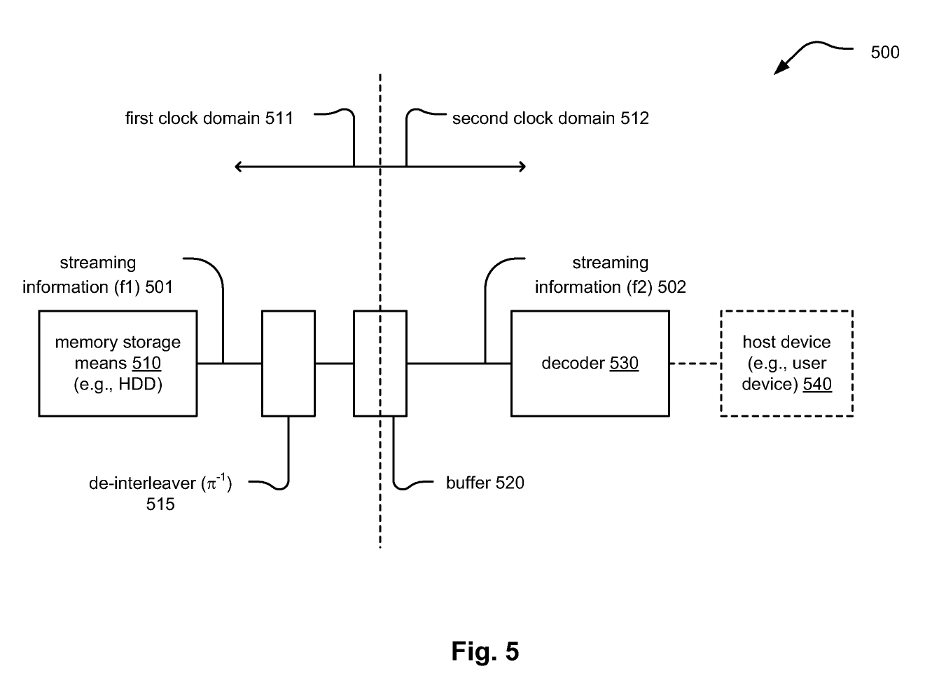

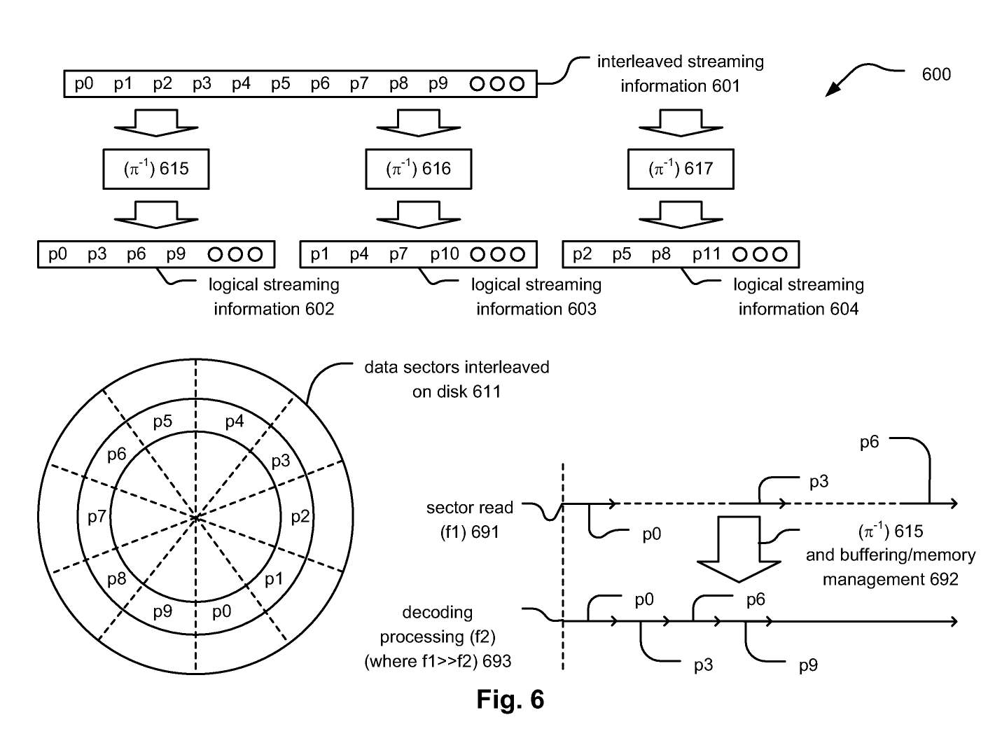

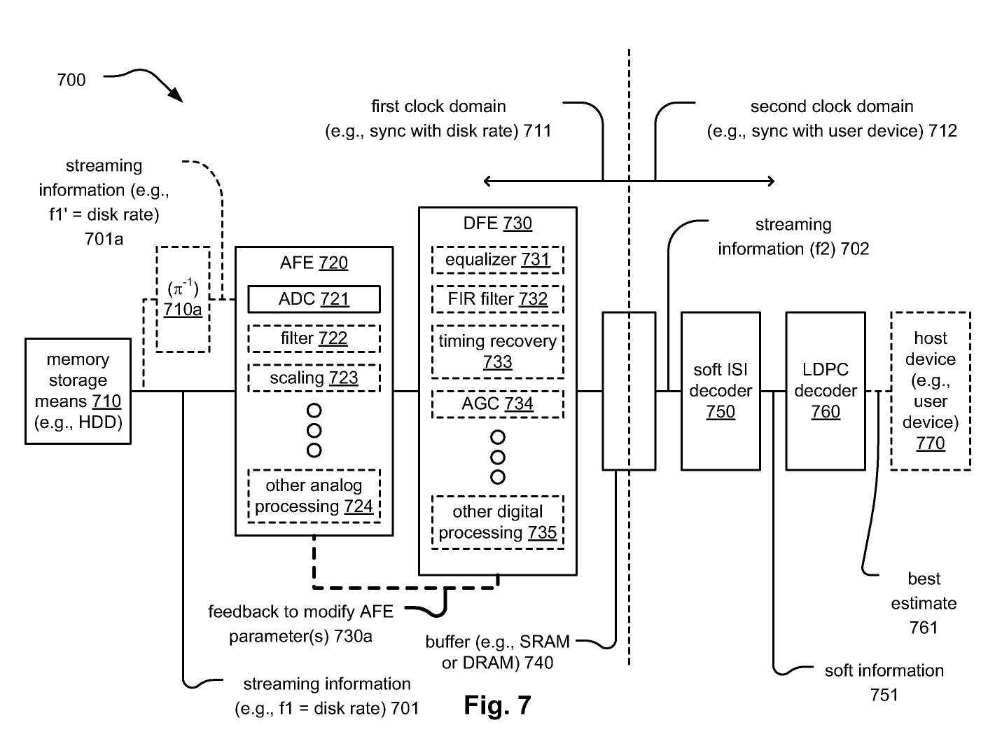

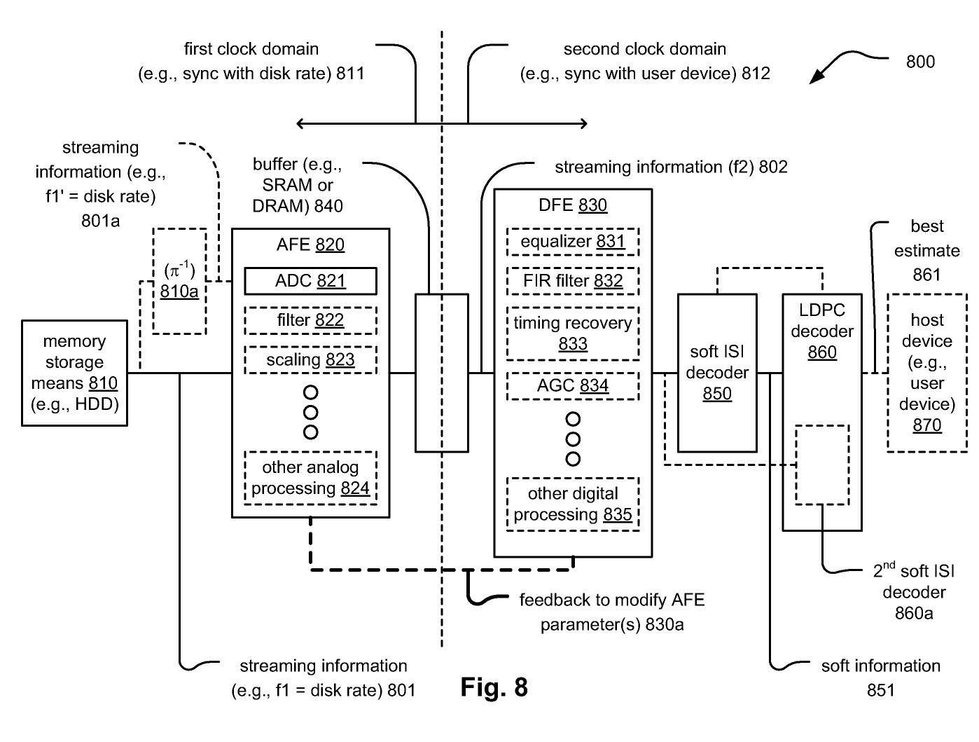

FIG. 3A illustrates an embodiment of a handheld audio unit 51. In particular, disk drive unit 100 can be implemented in the handheld audio unit 51. In one possible embodiment, the disk drive unit 100 can include a small form factor magnetic hard disk whose disk 102 has a diameter 1.8″ or smaller that is incorporated into or otherwise used by handheld audio unit 51 to provide general storage or storage of audio content such as motion picture expert group (MPEG) audio layer 3 (MP3) files or Windows Media Architecture (WMA) files, video content such as MPEG4 files (or data comporting to any other form of MPEG standard including the various versions of video standards therein) for playback to a user, and/or any other type of information that may be stored in a digital format. While the handheld audio unit 51 may be incapable to perform playback of the video content of digital stored within the disk drive unit 100 included therein, the disk drive unit 100 can nevertheless store that information.

FIG. 3B illustrates an embodiment of a handheld video unit 52. In particular, disk drive unit 100 can be implemented in the handheld video unit 52. The handheld audio unit 52 can also be designed to perform playback of digital audio data as well as digital video data. In one possible embodiment, disk drive unit 100 can include a small form factor magnetic hard disk whose disk 102 has a diameter 1.8″ or smaller, a 2.5″ or 3.5″ drive or larger drive for applications such as enterprise storage applications. Disk drive 100 is incorporated into or otherwise used by handheld audio unit 52 to provide general purpose storage for any type of information in digital format including audio content such as motion picture expert group (MPEG) audio layer 3 (MP3) files or Windows Media Architecture (WMA) files, video content such as MPEG4 files (or data comporting to any other form of MPEG standard including the various versions of video standards therein) for playback to a user, and/or any other type of information that may be stored in a digital format.

FIG. 3C illustrates an embodiment of a wireless communication device 53. In particular, disk drive unit 100 can be implemented in the wireless communication device 53. In one possible embodiment, disk drive unit 100 can include a small form factor magnetic hard disk whose disk 102 has a diameter 1.8″ or smaller that is incorporated into or otherwise used by wireless communication device 53 to provide general storage or storage of audio content such as motion picture expert group (MPEG) audio layer 3 (MP3) files or Windows Media Architecture (WMA) files, video content such as MPEG4 files (or data comporting to any other form of MPEG standard including the various versions of video standards therein), JPEG (joint photographic expert group) files, bitmap files and files stored in other graphics formats that may be captured by an integrated camera or downloaded to the wireless communication device 53, emails, webpage information and other information downloaded from the Internet, address book information, and/or any other type of information that may be stored in a digital format.

In a possible embodiment, wireless communication device 53 is capable of communicating via a wireless telephone network such as a cellular, personal communications service (PCS), general packet radio service (GPRS), global system for mobile communications (GSM), and integrated digital enhanced network (iDEN) or other wireless communications network capable of sending and receiving telephone calls. Further, wireless communication device 53 is capable of communicating via the Internet to access email, download content, access websites, and provide steaming audio and/or video programming. In this fashion, wireless communication device 53 can place and receive telephone calls, text messages such as emails, short message service (SMS) messages, pages and other data messages that can include attachments such as documents, audio files, video files, images and other graphics.

FIG. 3D illustrates an embodiment of a television 54. The television 54 is operable to perform playback of digital information including digital video data and digital audio data within any one or a wide variety of formats including those which comport to various digital audio and video standards. The television 54 is implemented in the traditional screen size format (e.g., 4:3 aspect ratio). The television 54 can be coupled to another device that includes disk drive unit 100, or disk drive unit 100 can be implemented within the television 54 (i.e., integrated into the television 54).

In one possible embodiment, disk drive unit 100 can include a small form factor magnetic hard disk whose disk 102 has a diameter 1.8″ or smaller that is incorporated into or otherwise used by television to provide general storage or storage of audio content such as motion picture expert group (MPEG) audio layer 3 (MP3) files or Windows Media Architecture (WMA) files, video content such as MPEG4 files (or data comporting to any other form of MPEG standard including the various versions of video standards therein), JPEG (joint photographic expert group) files, bitmap files and files stored in other graphics formats, emails, webpage information and other information downloaded from the Internet, address book information, and/or any other type of information that may be stored in a digital format.

In other possible embodiments, disk drive unit 100 can include a magnetic hard disk whose disk 102 that has a diameter of another size including a size that is typical to a HDD or other memory storage device employed in the art within such audio or video data storage means such as those employed within DVRs (Digital Video Recorders).

FIG. 3E illustrates an embodiment of a HD (High Definition) television 55. The HD television 55 is operable to perform playback of digital information including digital video data and digital audio data within any one or a wide variety of formats including those which comport to various digital audio and video standards. The HD television 55 is implemented in a widescreen size format (e.g., 16:9 aspect ratio or other widescreen ratio). The HD television 55 can be coupled to another device that includes disk drive unit 100, or disk drive unit 100 can be implemented within the HD television 55 (i.e., integrated into the television 55).

In one possible embodiment, disk drive unit 100 can include a small form factor magnetic hard disk whose disk 102 has a diameter 1.8″ or smaller that is incorporated into or otherwise used by television to provide general storage or storage of audio content such as motion picture expert group (MPEG) audio layer 3 (MP3) files or Windows Media Architecture (WMA) files, video content such as MPEG4 files (or data comporting to any other form of MPEG standard including the various versions of video standards therein), JPEG (joint photographic expert group) files, bitmap files and files stored in other graphics formats, emails, webpage information and other information downloaded from the Internet, address book information, and/or any other type of information that may be stored in a digital format.

In other possible embodiments, disk drive unit 100 can include a magnetic hard disk whose disk 102 that has a diameter of another size including a size that is typical to a HDD or other memory storage device employed in the art within such audio or video data storage means such as those employed within DVRs (Digital Video Recorders).

FIG. 3F illustrates an embodiment of an audio device 56. This embodiment of the audio device 56 includes a non-portable audio device that is operable to perform playback of any one of a wide variety of digital audio data. This audio device 56 includes a number of speakers (e.g., tweeters, woofers, sub-woofers, and/or other speaker types) that are operable to perform the last leg of electric to acoustic conversion for playback of the digital audio data.

The audio device 56 can be coupled to another device that includes disk drive unit 100, or disk drive unit 100 can be implemented within the audio device 56 (i.e., integrated into the audio device 56).

In one possible embodiment, disk drive unit 100 can include a small form factor magnetic hard disk whose disk 102 has a diameter 1.8″ or smaller that is incorporated into or otherwise used by television to provide general storage or storage of audio content such as motion picture expert group (MPEG) audio layer 3 (MP3) files or Windows Media Architecture (WMA) files, video content such as MPEG4 files (or data comporting to any other form of MPEG standard including the various versions of video standards therein), JPEG (joint photographic expert group) files, bitmap files and files stored in other graphics formats, emails, webpage information and other information downloaded from the Internet, address book information, and/or any other type of information that may be stored in a digital format.

In other possible embodiments, disk drive unit 100 can include a magnetic hard disk whose disk 102 that has a diameter of another size as well. While the audio device 56 may be incapable to perform playback of the non-audio content of digital stored within the disk drive unit 100 included therein, the disk drive unit 100 can nevertheless store that information.

While a variety of types of devices have been illustrated and described above that are operable store and playback digital data that is provided in a streaming format, it is also noted any other type of device that includes a HDD or other memory storage device in which streaming information is provided there from can also employ various aspects of the invention.

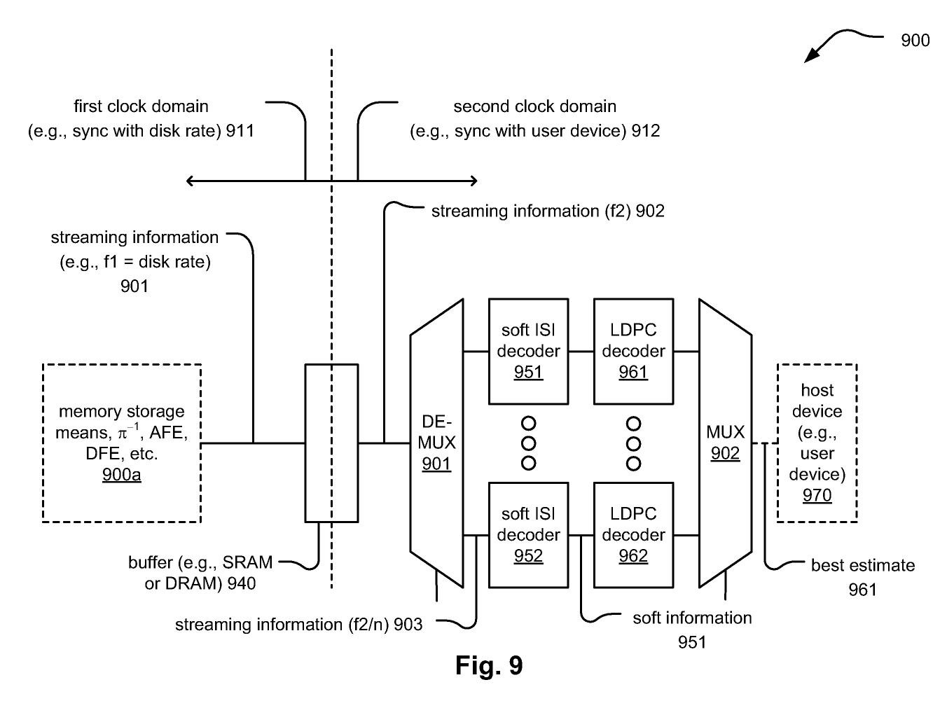

FIG. 4 and FIG. 5 illustrate embodiments of systems 400 and 500 that are operable to perform decoding of streaming information.

Referring to the system 400, memory storage means 410 (e.g., a HDD) is operable to provide streaming information 401 at a first rate (e.g., a first frequency shown as f1). The streaming information 401 is provided to a buffer 420. In this diagram, all operations to the left of the buffer 420 operate within a first clock domain 411, and all operations to the right of the buffer 420 operate within a second clock domain 412. The buffer 420 is operable to perform this decoupling of the rate at which the streaming information 401 is provided from the memory storage means 410.

Streaming information 402 is provided from the buffer 420 at a second rate (e.g., a second frequency shown as f2). The second rate at which the streaming information 402 is provided from the buffer 420 allows for a decoder 430 to perform a much wider variety and type of error correction codes (at an acceptably low and/or reasonable cost) than the prior art allows. By decoupling of the rate at which the streaming information 401 is provided from the memory storage means 410, the decoder 430 is operable to process at a relatively much slower rate, and this allows for the error of error correction codes that generally take a relatively long to decode (or are expensive to decode fast). That is to say, certain error correction codes require processing that takes longer and therefore cannot keep up with the first rate at which the streaming information 401 is provided from the memory storage means 410. However, by using the buffer 430, the first clock domain 411 can be decoupled from the second clock domain 412, and the decoder 430 is operable to perform the decoding processing at relatively much slower rates than the first rate at which the streaming information 401 is provided from the memory storage means 410.

After the decoder 430 has performed the decoding of the streaming information 402 provided from the buffer 420, the decoded information can be provided to a host device 440. The host device 440 can be a user device such as any device that is operable to perform playback of streaming digital information.

Referring to the system 500, memory storage means 510 (e.g., a HDD) is operable to provide streaming information 501 at a first rate (e.g., a first frequency shown as f1). This embodiment is analogous to the embodiment of the previous diagram, however, a de-interleaver (π⁻¹) 515 is interposed between the memory storage means 510 and a buffer 520. The data within the memory storage means 510 is physically interleaved therein. This allows for the ability to generate streaming information 502 at a second rate (e.g., a second frequency shown as f2) in another manner than provided within the previous embodiment.

In this embodiment of the system 500, if the interleaving of the information is actually on the media (e.g., the disk of an HDD), then the buffer 520 can be smaller when compared to the buffer 420 of the previous embodiment. The de-interleaver (π⁻¹) 515 can be viewed as operable to skip over (e.g., not read) many of the sectors from disk. It follows that periodic ‘bursts’ of information are provided from disk, and these are the desired sectors. The undesired sectors can be ignored and consequently will not fill up the buffer 520; this allows for a relatively smaller buffer to be employed in such an embodiment.

After undergoing the de-interleaving within the de-interleaver (π⁻¹) 515, the now-de-interleaved streaming information 501 is provided to the buffer 520. The buffer is operable to generate the logical streaming information which is the streaming information 502. In this diagram, all operations to the left of the buffer 520 operate within a first clock domain 511, and all operations to the right of the buffer 520 operate within a second clock domain 512. The buffer 520 is operable to perform this decoupling of the rate at which the streaming information 501 is provided from the memory storage means 510.

Streaming information 502 (i.e., which is a logical stream of information generated from the de-interleaved version of the streaming information 501) is provided from the buffer 520 at a second rate (e.g., a second frequency shown as f2). The second rate at which the streaming information 502 is provided from the buffer 520 allows for a decoder 530 to perform a much wider variety and type of error correction codes than the prior art allows. By decoupling of the rate at which the streaming information 501 is provided from the memory storage means 510, the decoder 530 is operable to process at a relatively much slower rate, and this allows for the error of error correction codes that generally take a relatively long to decode. That is to say, certain error correction codes require processing that takes longer and therefore cannot keep up with the first rate at which the streaming information 501 is provided from the memory storage means 510. However, by using the buffer 520, the first clock domain 511 can be decoupled from the second clock domain 512, and the decoder 530 is operable to perform the decoding processing at relatively much slower rates than the first rate at which the streaming information 501 is provided from the memory storage means 510.

After the decoder 530 has performed the decoding of the streaming information 502 provided from the buffer 520, the decoded information can be provided to a host device 540. The host device 540 can be a user device such as any device that is operable to perform playback of streaming digital information.

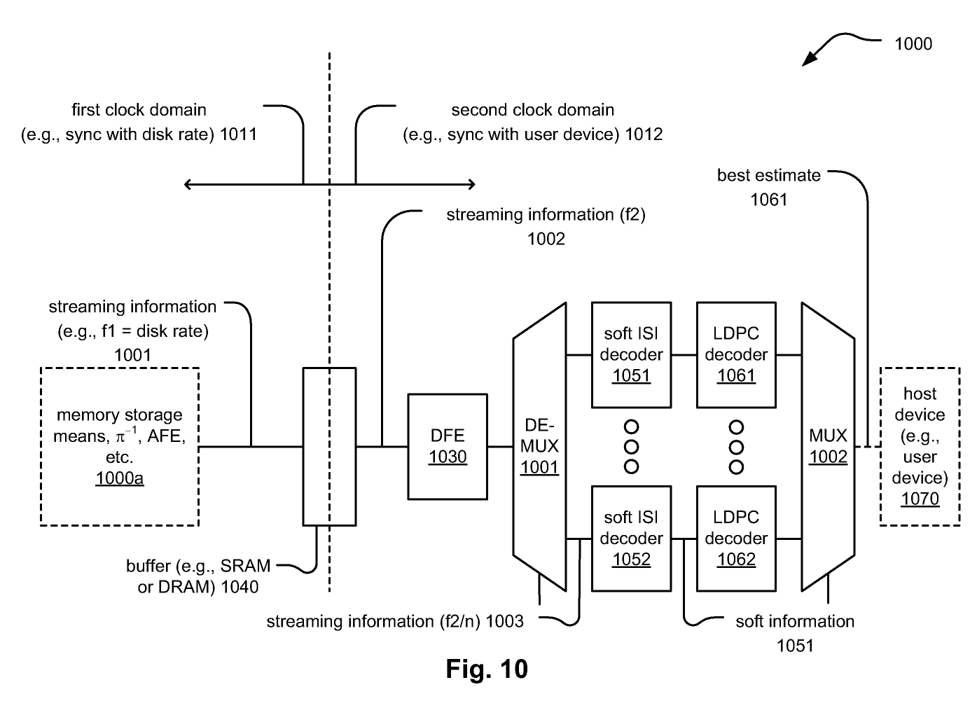

FIG. 6 illustrates an alternative embodiment of a physical interleaving 600 of data on a disk within a HDD or other memory storage system. Interleaved streaming information 601 corresponds to the data sectors that are interleaved on a disk of a memory storage means, as indicated by reference numeral 611. When following a track around the disk, it can be seen that the interleaved streaming information 601 corresponds to the particular successive data sectors on the disk. However, these data sectors on the disk are physically interleaved on the disk.

Depending on the particular interleaving employed when physically interleaving the data sectors on the disk, an appropriately implemented de-interleaver (π⁻¹) is employed to generate logical streaming information that has a rate at which decoding processing can be implemented thereon at a relatively much slower rate than that which the interleaved streaming information 601 is provided from disk. In other words, the physical interleaving of the interleaved streaming information 601 on the disk allows for the formation of one or more logical streaming information such that the rate of that logical streaming information is relatively less than the rate at which the interleaved streaming information 601 is provided from disk.

A few possible embodiments of de-interleaving are shown here, and these embodiments are exhaustive of a very wide variety of possible interleaving/de-interleaving approaches that are possible.

Looking at the de-interleaver (π⁻¹) 615, is can be seen that from the interleaved streaming information 601 that includes information p0, p1, p2, . . . , and so on, logical streaming information 602 (that includes p0, p3, p6, p9, . . . , and so on) is generated there from. As can be seen, a first data sector (p0) is taken from the interleaved streaming information 601, then two subsequent data sectors are skipped, and then a fourth data sector (p3) is taken from the interleaved streaming information 601, and so on according to the operation of the de-interleaver (π⁻¹) 615.

Looking at the de-interleaver (π⁻¹) 616, is can be seen that from the interleaved streaming information 601 that includes information p0, p1, p2, . . . , and so on, logical streaming information 603 (that includes p1, p4, p7, p10, . . . , and so on) is generated there from. As can be seen, a second data sector (p1) is taken from the interleaved streaming information 601, then two subsequent data sectors are skipped, and then a fifth data sector (p4) is taken from the interleaved streaming information 601, and so on according to the operation of the de-interleaver (π⁻¹) 616.

Looking at the de-interleaver (π⁻¹) 617, is can be seen that from the interleaved streaming information 601 that includes information p0, p1, p2, . . . , and so on, logical streaming information 604 (that includes p2, p5, p8, p11, . . . , and so on) is generated there from. As can be seen, a third data sector (p2) is taken from the interleaved streaming information 601, then two subsequent data sectors are skipped, and then a sixth data sector (p5) is taken from the interleaved streaming information 601, and so on according to the operation of the de-interleaver (π⁻¹) 617.

In some embodiments, a single de-interleaver (π⁻¹) can be re-used and employed to perform the operations of each of the de-interleaver (π⁻¹) 615, de-interleaver (π⁻¹) 616, and de-interleaver (π⁻¹) 617.

Looking at the lower right hand side of this diagram (which operates according to the de-interleaver (π⁻¹) 615), the sector read operations are performed according to a first rate or frequency, shown as f1, as indicated by reference numeral 691. Then, after undergoing the de-interleaving as provided by the de-interleaver (π⁻¹) 615 and any appropriate buffering/memory management as indicated by the reference numeral 692 to generate the appropriate logical streaming information 602, then the decoding processing 693 is performed at a second rate or frequency, shown as f2, that is generally much less than the first rate or frequency, shown as f1, at which the interleaved streaming information 601 is provided from disk.

This physical interleaving of the data sectors on disk and the de-interleaving of the interleaved streaming information 601 (i.e., by using an appropriate de-interleaver (π⁻¹) and any appropriate buffering/memory management) that is provided from disk is yet another means by which information can be provided from a disk at a first rate or within a first clock domain, and then the decoding processing of that streaming information can be performed at a second rate or within a second clock domain.

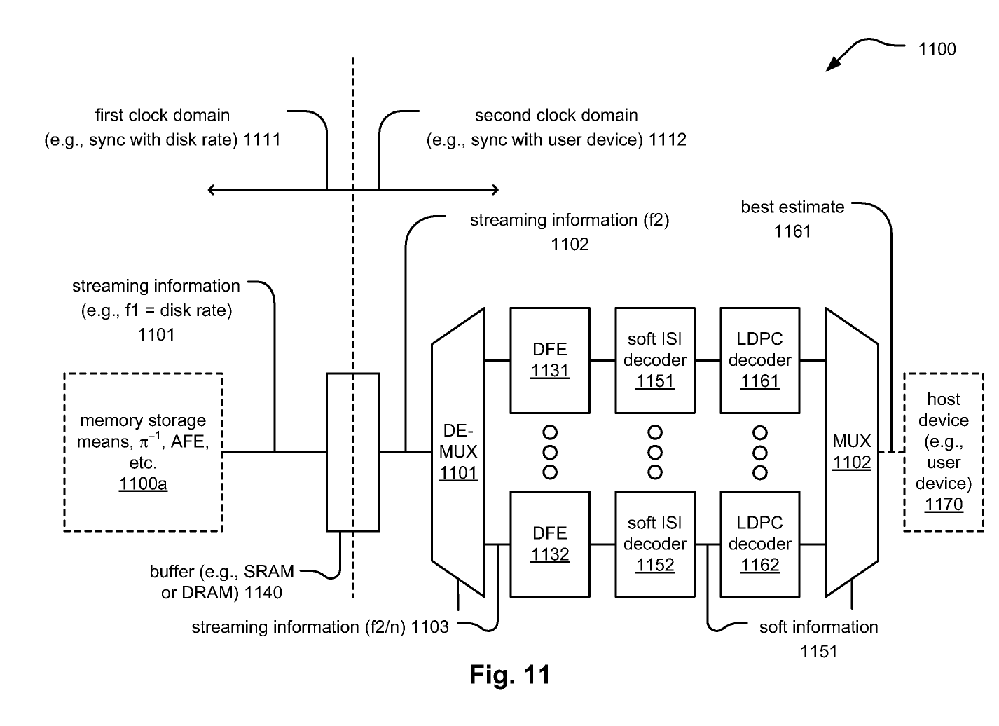

FIG. 7 and FIG. 8 illustrate other embodiments of systems 700 and 800 that are operable to perform decoding of streaming information.

Referring to the system 700, streaming information 701 is provided from memory storage means 710 (e.g. a HDD or other storage means) at a first rate. Generally, this first rate at which the streaming information 701 is provided from the memory storage means 710 is at the disk rate, which can generally be viewed as being the rate at which information is streamed out of the actual storage media (e.g., from the disk of a HDD).

An analog front end (AFE) 720 receives information from the memory storage means 710 and performs any appropriate analog processing therein. It is also noted that an alternative embodiment could include a de-interleaver (π⁻¹) 710a interposed between the memory storage means 710 and the AFE 720. The operation of the de-interleaver (π⁻¹) 710a would change the average rate of the information down to the required rate, but the data would still burst over.

For example, at a minimum, the AFE 720 is operable to perform digital sampling of the streaming information 701 using an analog to digital converter (ADC) 721. In some embodiments, the AFE 720 is also operable to perform filtering 722, scaling 723, and/or any other analog processing 724 that is desired or appropriate in a particular application. The now digital version of the streaming information 701 is then provided to a digital front end (DFE) which can provide any one or more of a variety of digital signal processing operations including any one or more of equalization using an equalizer 731, filtering using some digital filtering means such as a finite impulse response (FIR) filter 732, timing recovery 733, any gain adjustment or scaling using such a means or an automatic gain controller (AGC) 734, and/or any other digital processing 735 that is desired or appropriate in a particular application.

In addition, it is noted that a relatively high bandwidth feedback control channel 730a (when compared to the next embodiment) can be implemented from the DFE 730 to the AFE 720 to allow the adjustment/modification of any one or more of operational parameters employed within any processing module or process within the AFE 730. For example, scaling 723 within the AFE 720 (before ADC sampling) could be adjusted based on the results of the DFE 730.

The digital and now-digital signal processed version of the streaming information 701 is then provided to a buffer 740. The buffer 740 can be implemented using any of a wide variety of means including SRAM (Static Random Access Memory), DRAM (Dynamic Random Access Memory), some other buffering means or combination thereof. In this diagram, all operations to the left of the buffer 740 operate within a first clock domain 711, and all operations to the right of the buffer 740 operate within a second clock domain 712. All operations within the first clock domain 711 can all be performed in synchronization with the disk rate. All operations within the second clock domain 712 can all be performed in synchronization with a rate at which a user device is designed to receive streaming information.

The buffer 740 is operable to perform this decoupling of the rate at which the streaming information 701 is provided from the memory storage means 710. Streaming information 702 is provided from the buffer 740 at a second rate (e.g., a second frequency shown as f2). The second rate at which the streaming information 702 is provided from the buffer 740 allows for the use of a much wider variety and type of error correction codes than the prior art allows. While a variety of codes and decoding approaches can be employed, this embodiment includes a soft ISI (Inter-Symbol Interference) decoder 750 that is operable to receive the streaming information 702 and to generate soft information 751 there from. In some embodiments, this soft information 751 is generated in a format of LLRs (log likelihood ratios). The soft ISI decoder 750 is operable to generate at least one soft decision within the soft information 751, and an LDPC (Low Density Parity Check) decoder 760 is operable to process the at least one soft decision within the soft information 751 thereby making a best estimate 761 of the streaming information 702 that is provided from the buffer 740.

After the LDPC decoder 760 has performed the decoding of the streaming information 702 provided from the buffer 740, the decoded information can be provided to a host device 770. The host device 770 can be a user device such as any device that is operable to perform playback of streaming digital information.

Referring to the system 800, this embodiment is analogous to the previous embodiment with at least one difference being that the DFE 830 of FIG. 8 operates within a second clock domain 812. By operating within the second clock domain 812, the DFE 830 also benefits from the greater flexibility, in that, the DFE 830 need not operate synchronously with the rate at which streaming information 801 is provided from memory storage means 810.

Looking at the diagram, the streaming information 801 is provided from memory storage means 810 (e.g. a HDD or other storage means) at a first rate. Generally, this first rate at which the streaming information 801 is provided from the memory storage means 810 is at the disk rate, which can generally be viewed as being the rate at which information is streamed out of the actual storage media (e.g., from the disk of a HDD).

An analog front end (AFE) 820 receives information from the memory storage means 810 and performs any appropriate analog processing therein. It is also noted that an alternative embodiment could include a de-interleaver (π⁻¹) 810a interposed between the memory storage means 810 and the AFE 820. The operation of the de-interleaver (π⁻¹) 810a would change the average rate of the information down to the required rate, but the data would still burst over.

For example, at a minimum, the AFE 820 is operable to perform digital sampling of the streaming information 801 using an analog to digital converter (ADC) 821. In some embodiments, the AFE 820 is also operable to perform filtering 822, scaling 823, and/or any other analog processing 824 that is desired or appropriate in a particular application.

The AFE signal processed version of the streaming information 801 is then provided to a buffer 840. The buffer 840 can be implemented using any of a wide variety of means including SRAM (Static Random Access Memory), DRAM (Dynamic Random Access Memory), some other buffering means or combination thereof. In this diagram, all operations to the left of the buffer 840 operate within a first clock domain 811, and all operations to the right of the buffer 840 operate within a second clock domain 812. All operations within the first clock domain 811 can all be performed in synchronization with the disk rate. All operations within the second clock domain 812 can all be performed in synchronization with a rate at which a user device is designed to receive streaming information.

The buffer 840 is operable to perform this decoupling of the rate at which the streaming information 801 is provided from the memory storage means 810. Streaming information 802 is provided from the buffer 840 at a second rate (e.g., a second frequency shown as f2) to a DFE 830. The second rate at which the streaming information 802 is provided from the buffer 840 allows for the use of a much wider variety and type of error correction codes than the prior art allows.

The DFE 830 can then provide any one or more of a variety of digital signal processing operations on streaming information 802 including any one or more of equalization using an equalizer 831, filtering using some digital filtering means such as a finite impulse response (FIR) filter 832, timing recovery 833, any gain adjustment or scaling using such a means or an automatic gain controller (AGC) 834, and/or any other digital processing 835 that is desired or appropriate in a particular application.

In addition, it is noted that a relatively lower bandwidth feedback (when compared to the previous embodiment) control channel 830a can be implemented from the DFE 830 to the AFE 820 to allow the adjustment/modification of any one or more of operational parameters employed within any processing module or process within the AFE 830. For example, scaling 823 within the AFE 820 (before ADC sampling) could be adjusted based on the results of the DFE 830.

While a variety of codes and decoding approaches can be employed, this embodiment includes a soft ISI (Inter-Symbol Interference) decoder 850 that is operable to receive the DFE processed version of the streaming information 802 and to generate soft information 851 there from. In some embodiments, this soft information 851 is generated in a format of LLRs (log likelihood ratios). The soft ISI decoder 850 is operable to generate at least one soft decision within the soft information 851, and an LDPC (Low Density Parity Check) decoder 860 is operable to process the at least one soft decision within the soft information 851 thereby making a best estimate 861 of the streaming information 802 that is provided from the buffer 840. It is also noted that in some embodiments, the soft ISI decoder 850 can itself be implemented as part of the DFE 830.

After the LDPC decoder 860 has performed the decoding of the streaming information 802 provided from the buffer 840, the decoded information can be provided to a host device 870. The host device 870 can be a user device such as any device that is operable to perform playback of streaming digital information.

It is also noted that alternative embodiments (e.g., modifications of FIG. 7 and/or FIG. 8) could include a feedback path from the LDPC decoder 860 to the soft ISI decoder 850 to allow for ‘turbo decoding’ in which the current bit estimates provided from the LDPC decoder 860 could be employed as updated/‘a priori’ information for use in generating a next iteration of soft information 851 within soft ISI decoder 850. Also, the LDPC decoder 860 could be implemented to include a 2^{nd} soft ISI decoder 860a, such that the 2^{nd} soft ISI decoder 860a takes in not only input from the DFE 830 but also from ‘soft information’ generated within the LDPC decoder 860 itself during a particular decoding iteration.

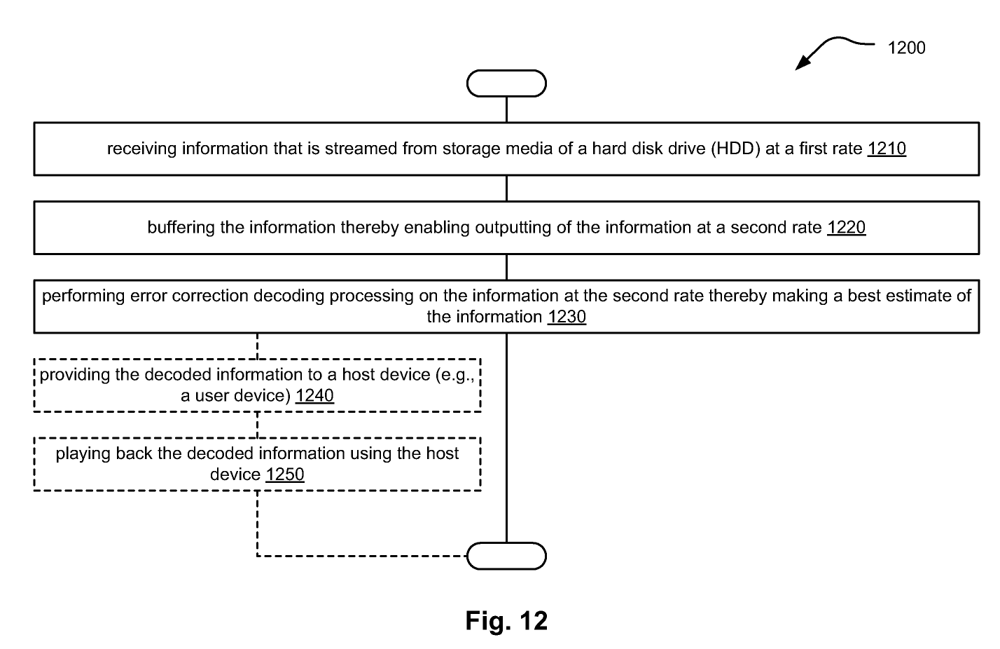

FIG. 9, FIG. 10, and FIG. 11 illustrates embodiments of systems 900, 1000, and 1100 that are operable to perform decoding of streaming information by employing some type of parallel architecture. Such a parallel architecture can be useful in embodiments, among others, when even the lower average streaming rate is still too high to allow for a lower (or lowest) cost and lower (or lowest) power non-parallel solution.

Referring to the system 900, certain portions of this embodiment are analogous to the embodiment depicted in FIG. 7 in which the DFE 730 therein is situated and implemented within the first clock domain 711. Looking at FIG. 9, the first clock domain 911 can be viewed as being similar to the first clock domain 711 within the FIG. 7 (e.g., including memory storage means, de-interleaver (π⁻¹), an AFE, and a DFE, etc. as shown corporately by reference numeral 900a). Streaming information 901 is provided to a buffer 940. The rate at which the streaming information 901 is provided is depicted by a frequency, f1, that is generally governed by the disk rate at which the streaming information is provided from the memory storage means. Also, the AFE and the DFE generally also operate in accordance with the first clock domain 911 and are synchronous with the disk rate as well.

As within other embodiment, in this diagram, all operations to the left of the buffer 940 operate within a first clock domain 911, and all operations to the right of the buffer 940 operate within a second clock domain 912. All operations within the first clock domain 911 can all be performed in synchronization with the disk rate. All operations within the second clock domain 912 can all be performed in synchronization with a rate at which a user device is designed to receive streaming information.

The buffer 940 is operable to perform this decoupling of the rate at which the streaming information 901 is provided from the memory storage means. Streaming information 902 is provided from the buffer 940 at a second rate (e.g., a second frequency shown as f2). The second rate at which the streaming information 902 is provided from the buffer 940 allows for the use of a much wider variety and type of error correction codes than the prior art allows.

In the particular application in which the streaming information 901 has been encoded using an LDPC code, the properties of LDPC codes allow for a great deal of parallel implementation in the functional blocks and operations within the second clock domain 912. For example, a de-multiplexor (DEMUX) 901 is operable to perform de-serialization of the streaming information 902 into a plurality of streams each having a reduced rate. For example, if the streaming information 902 has a rate of f2, and if the DEMUX 901 partitions the streaming information 902 into “n” streams, then each stream can have a rate as low as f2/n as shown by reference numeral 903.

Each path in which an individual stream is processed to the right hand side of the DEMUX 901 can include a soft ISI decoder and an LDPC decoder just as within the embodiment of FIG. 7 include a single soft ISI decoder 750 and a single LDPC decoder 760. Specifically, in this diagram, a first processing stream includes a soft ISI decoder 951 and an LDPC decoder 961, and an n-th processing stream includes a soft ISI decoder 952 and an LDPC decoder 962. Looking at one stream, the soft ISI decoder 952 is operable to generate at least one soft decision within the soft information 951, and the LDPC decoder 962 is operable to process the at least one soft decision within the soft information 951 thereby making a best estimate of portion of the streaming information 903 that is provided from the DEMUX 901. A multiplexor (MUX) 902 then operates to combine (e.g., serialize) all of the best estimates generated for each of the n streams into a single best estimate 961. This decoded information (i.e., the best estimate 961, which is the best estimate of the streaming information 902) can be provided to a host device 970. The host device 970 can be a user device such as any device that is operable to perform playback of streaming digital information.

Referring to the system 1000, certain portions of this embodiment are analogous to the embodiment depicted in FIG. 8 in which the DFE 830 therein is situated and implemented within the second clock domain 812. Looking at FIG. 10, the first clock domain 1011 can be viewed as being similar to the first clock domain 811 within the FIG. 8 (e.g., including memory storage means, de-interleaver (π⁻¹), an AFE, etc. as shown corporately by reference numeral 1000a). Streaming information 1001 is provided to a buffer 1040. The rate at which the streaming information 1001 is provided is depicted by a frequency, f1, that is generally governed by the disk rate at which the streaming information is provided from the memory storage means. Also, the AFE generally also operates in accordance with the first clock domain 1011 and is synchronous with the disk rate as well. However, a DFE 1030 operates in accordance with a second clock domain 1012 and need not be synchronous with the disk rate.

As within other embodiment, in this diagram, all operations to the left of the buffer 1040 operate within a first clock domain 1011, and all operations to the right of the buffer 1040 operate within a second clock domain 1012. All operations within the first clock domain 1011 can all be performed in synchronization with the disk rate. All operations within the second clock domain 1012 can all be performed in synchronization with a rate at which a user device is designed to receive streaming information.

The buffer 1040 is operable to perform this decoupling of the rate at which the streaming information 1001 is provided from the memory storage means. Streaming information 1002 is provided from the buffer 1040 at a second rate (e.g., a second frequency shown as f2) and then delivered to a DFE 1030. Again, the second rate at which the streaming information 1002 is provided from the buffer 1040 allows for the use of a much wider variety and type of error correction codes than the prior art allows.

In the particular application in which the streaming information 1001 has been encoded using an LDPC code, the properties of LDPC codes allow for a great deal of parallel implementation in the functional blocks and operations within the second clock domain 1012. For example, after undergoing processing by the DFE 1030, the now-digitally processed streaming information 1002 is provided to a DEMUX 1001 that is operable to perform de-serialization of the digitally processed streaming information 1002 into a plurality of streams each having a reduced rate. For example, if the streaming information 1002 has a rate of f2, and if the DEMUX 1001 partitions the streaming information 1002 into “n” streams, then each stream can have a rate as low as f2/n as shown by reference numeral 1003.

Each path in which an individual stream is processed to the right hand side of the DEMUX 1001 can include a soft ISI decoder and an LDPC decoder just as within the embodiment of FIG. 8 include a single soft ISI decoder 850 and a single LDPC decoder 860. Specifically, in this diagram, a first processing stream includes a soft ISI decoder 1051 and an LDPC decoder 1061, and an n-th processing stream includes a soft ISI decoder 1052 and an LDPC decoder 1062. Looking at one stream, the soft ISI decoder 1052 is operable to generate at least one soft decision within the soft information 1051, and the LDPC decoder 1062 is operable to process the at least one soft decision within the soft information 1051 thereby making a best estimate of portion of the streaming information 1003 that is provided from the DEMUX 1001. A MUX 1002 then operates to combine (e.g., serialize) all of the best estimates generated for each of the n streams into a single best estimate 1061. This decoded information (i.e., the best estimate 1061, which is the best estimate of the streaming information 1002) can be provided to a host device 1070. The host device 1070 can be a user device such as any device that is operable to perform playback of streaming digital information.

Referring to the system 1100, this embodiment is analogous to the previous embodiment of FIG. 10 with a difference being that the DFE is also implemented in a parallel architecture.

As within other embodiment, in this diagram, all operations to the left of the buffer 1140 operate within a first clock domain 1111, and all operations to the right of the buffer 1140 operate within a second clock domain 112.

Looking at FIG. 11, the first clock domain 1111 can be viewed as being similar to the first clock domain 811 within the FIG. 8 or the first clock domain 1011 within the FIG. 10 (e.g., including memory storage means, de-interleaver (π⁻¹), an AFE, etc. as shown corporately by reference numeral 1100a).

All operations within the first clock domain 1111 can all be performed in synchronization with the disk rate. All operations within the second clock domain 1112 can all be performed in synchronization with a rate at which a user device is designed to receive streaming information.

The buffer 1140 is operable to perform this decoupling of the rate at which the streaming information 1101 is provided from the memory storage means. Streaming information 1102 is provided from the buffer 1140 at a second rate (e.g., a second frequency shown as f2) and then delivered to a DEMUX 1101. Again, the second rate at which the streaming information 1102 is provided from the buffer 1140 allows for the use of a much wider variety and type of error correction codes than the prior art allows.

In the particular application in which the streaming information 1101 has been encoded using an LDPC code, the properties of LDPC codes allow for a great deal of parallel implementation in the functional blocks and operations within the second clock domain 1112. For example, the DEMUX 1101 is operable to perform de-serialization of the streaming information 1102 into a plurality of streams each having a reduced rate. For example, if the streaming information 1102 has a rate of f2, and if the DEMUX 1101 partitions the streaming information 1102 into “n” streams, then each stream can have a rate as low as f2/n as shown by reference numeral 1103.

Each path in which an individual stream is processed to the right hand side of the DEMUX 1101 can include a reduced size DFE, a soft ISI decoder, and an LDPC decoder just as within previous embodiment that include a single DFE, a single soft ISI decoder, and a single LDPC decoder. Specifically, in this diagram, a first processing stream includes a DFE 1131, a soft ISI decoder 1151, and an LDPC decoder 1161, and an n-th processing stream includes a DFE 1132, a soft ISI decoder 1152 and an LDPC decoder 1162. Looking at one stream, DEMUX 1101 is operable to provide the steaming information 1103 to the DFE 1132. Then, the soft ISI decoder 1152 is operable to generate at least one soft decision within the soft information 1151, and the LDPC decoder 1162 is operable to process the at least one soft decision within the soft information 1151 thereby making a best estimate of portion of the streaming information 1103 that is provided from the DEMUX 1101. A MUX 1102 then operates to combine (e.g., serialize) all of the best estimates generated for each of the n streams into a single best estimate 1161. This decoded information (i.e., the best estimate 1161, which is the best estimate of the streaming information 1102) can be provided to a host device 1170. The host device 1170 can be a user device such as any device that is operable to perform playback of streaming digital information.

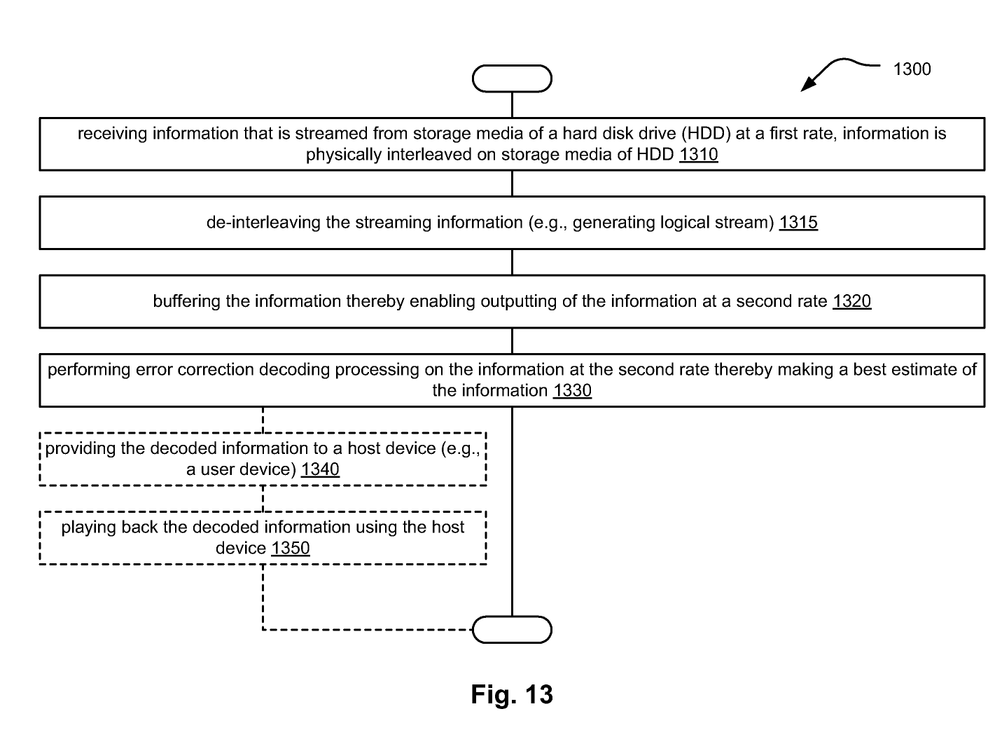

FIG. 12 and FIG. 13 illustrate embodiments of methods 1200 and 1300 that are operable to perform decoding of streaming information.

Referring to the method 1200, the method 1200 begins by receiving information that is streamed from storage media of a HDD at a first rate, as shown in a block 1210. The method 1200 then continues by buffering the information thereby enabling the outputting of the information from the buffer at a second rate, as shown in a block 1220. This buffering/queuing of the information can be performed using any of a variety of means, including SRAM, DRAM, other memory means, and/or any combination thereof. The method 1200 then continues by performing error correction decoding processing on the information at the second rate thereby making a best estimate of the information, as shown in a block 1230.

In some embodiments, the method 1200 also involves providing the decoded information to a host device as shown in a block 1240. Within the block 1240, the host device can be a user device such as any device that is operable to perform playback of streaming digital information. Then, the method 1200 can also involve playing back the decoded into using the host device, as shown in a block 1250.

Referring to the method 1300, this embodiment is somewhat analogous to the previous embodiment with a difference being that streaming information is provided from a storage media on which it is physically interleaved thereon.

The method 1300 begins by information that is streamed from storage media of a HDD at a first rate, as shown in a block 1310. The information is physically interleaved on the storage media of the HDD. The method 1300 then continues by de-interleaving the streaming information as shown in a block 1315. The operation of the block 1315 can be viewed as involving generating one or more logical streams from the streaming information received from the storage media of the HDD.

The method 1300 then continues by buffering the information thereby enabling the outputting of the information from the buffer at a second rate, as shown in a block 1320. This buffering/queuing of the information can be performed using any of a variety of means, including SRAM, DRAM, other memory means, and/or any combination thereof. The method 1300 then continues by performing error correction decoding processing on the information at the second rate thereby making a best estimate of the information, as shown in a block 1330.

In some embodiments, the method 1300 also involves providing the decoded information to a host device as shown in a block 1340. Within the block 1340, the host device can be a user device such as any device that is operable to perform playback of streaming digital information. Then, the method 1300 can also involve playing back the decoded into using the host device, as shown in a block 1350.

It is also noted that the methods described within the preceding figures may also be performed within any appropriate system and/or apparatus designs without departing from the scope and spirit of the invention.

In view of the above detailed description of the invention and associated drawings, other modifications and variations will now become apparent. It should also be apparent that such other modifications and variations may be effected without departing from the spirit and scope of the invention.

What is claimed is:

1. An apparatus, comprising:
a front end processor that is operable that is operable to receive information that is streamed from storage media of a hard disk drive (HDD) at a first rate;
a buffer that is operable to:
receive the information from the front end processor at the first rate; and
store the information so that the information can be output there from at a second rate; and
a decoder that is operable to perform error correction decoding processing on the information received from the buffer thereby making a best estimate of the information, wherein the error correction decoding processing is performed at the second rate.

2. The apparatus of claim 1, wherein:
the front end processor operates within a first clock domain that corresponds to a disk rate of the storage media; and
the decoder operates within a second clock domain.

3. The apparatus of claim 1, wherein:
the front end processor includes an AFE (Analog Front End) and a DFE (Digital Front End);
the AFE is operable to:
receive an analog signal that includes the information that is streamed from the storage media of the HDD; and
process the analog signal by performing at least sampling thereby generating a digital signal; and
the DFE is operable to:
receive the digital signal from the AFE; and
process the digital signal by performing at least one of equalization, filtering, timing recovery processing, and scaling thereby generating a processed digital signal that includes the information that is received by the buffer.

4. The apparatus of claim 1, wherein:
the decoder includes a soft ISI (Inter-Symbol Interference) decoder and an LDPC (Low Density Parity Check) decoder;
the soft ISI decoder is operable to generate at least one soft decision corresponding to the information received from the buffer at the second rate; and
the LDPC decoder is operable to process the at least one soft decision thereby making the best estimate of the information.

5. The apparatus of claim 1, further comprising:
a user device that is operable to perform playback of the best estimate of the information; and wherein:
the first rate corresponds to a disk rate of the storage media; and
the second rate corresponds to a rate at which the user device is designed to perform playback of information.

6. The apparatus of claim 5, wherein:
the user device is:
a television or a high-definition television that is operable to perform playback of information that comports with at least one MPEG (Moving Picture Experts Group) format or another digital video format; or
a digital audio device that is operable to perform playback of information that comports with MP3 (Moving Picture Experts Group Audio Layer-3) or another digital audio format.

7. The apparatus of claim 1, wherein:
the decoder includes a plurality of LDPC (Low Density Parity Check) decoders implemented in a parallel architecture.

8. The apparatus of claim 1, wherein:
the buffer is implemented using SRAM (Static Random Access Memory) or DRAM (Dynamic Random Access Memory).

9. The apparatus of claim 1, wherein:
the first rate at which the information is streamed from the storage media of the HDD is greater than a maximum rate at which the decoder is operable to perform error correction decoding processing.

10. The apparatus of claim 1, wherein:
the information that is streamed from the storage media of the HDD at the first rate is in LDPC (Low Density Parity Check) code block format having an LDPC code block size; and
the LDPC code block size is such that a maximum rate at which the decoder is operable to perform error correction decoding processing of an LDPC code block of the information is less than the first rate.

11. An apparatus, comprising:
an AFE (Analog Front End) is operable that is operable to:
receive a streaming signal from storage media of a hard disk drive (HDD) at a first rate that corresponds to a disk rate of the storage media; and
process the streaming signal by performing at least sampling thereby generating a digital signal;
a DFE (Digital Front End) that is operable to:
receive the digital signal from the AFE; and
process the digital signal by performing at least one of equalization, filtering, timing recovery processing, and scaling thereby generating a processed digital signal;
a buffer that is operable to:
receive the processed digital signal from the DFE at the first rate; and
store the processed digital signal so that the processed digital signal can be output there from at a second rate;
a soft ISI (Inter-Symbol Interference) decoder is operable to generates at least one soft decision corresponding to information encoded within the processed digital signal that is received from the buffer at the second rate; and
an LDPC (Low Density Parity Check) decoder is operable to process the at least one soft decision thereby making a best estimate of the information encoded within the processed digital signal.

12. The apparatus of claim 11, wherein:
the AFE and the DFE operate within a first clock domain that corresponds to the disk rate of the storage media; and
the soft ISI decoder and the LDPC decoder operate within a second clock domain.

13. The apparatus of claim 11, further comprising:
a user device that is operable to perform playback of the best estimate of the information; and wherein:
the first rate corresponds to a disk rate of the storage media; and
the second rate corresponds to a rate at which the user device is designed to perform playback of information.

14. The apparatus of claim 13, wherein:
the user device is:
a television or a high-definition television that is operable to perform playback of information that comports with at least one MPEG (Moving Picture Experts Group) format or another digital video format; or
a digital audio device that is operable to perform playback of information that comports with MP3 (Moving Picture Experts Group Audio Layer-3) or another digital audio format.

15. The apparatus of claim 11, wherein:
the buffer is implemented using SRAM (Static Random Access Memory) or DRAM (Dynamic Random Access Memory).

16. The apparatus of claim 11, wherein:
the first rate at which the streaming signal is provided from the storage media of the HDD is greater than a maximum rate at which either of the soft ISI decoder or the LDPC decoder is operable to perform decoding processing.

17. A method, comprising:
receiving information that is streamed from storage media of a hard disk drive (HDD) at a first rate;
buffering the information thereby enabling outputting of the information at a second rate; and
performing error correction decoding processing on the information at a second rate thereby making a best estimate of the information.

18. The method of claim 17, wherein:
the error correction decoding processing includes soft ISI (Inter-Symbol Interference) decoding and LDPC (Low Density Parity Check) decoding;
the soft ISI decoder includes generating at least one soft decision corresponding to the information received at the second rate; and
the LDPC decoding includes processing the at least one soft decision thereby making the best estimate of the information.

19. The method of claim 17, further comprising:
performing playback of the best estimate of the information on a user device; and wherein:
the first rate corresponds to a disk rate of the storage media; and
the second rate corresponds to a rate at which the user device is designed to perform playback of information.

20. The method of claim 17, wherein:
the buffering of the information is implemented using SRAM (Static Random Access Memory) or DRAM (Dynamic Random Access Memory).
